(19) United States
(12) Patent Application Publication
(10) Pub. No.: US 2005/0194984 A1
(43) Pub. Date: Sep. 8, 2005

(54) Testing apparatus and testing method

(75) Inventor: Jun-Cheng Chiang, Taoyuan County (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/007,349

(22) Filed: Dec. 9, 2004

(30) Foreign Application Priority Data
Mar. 5, 2004 (TW) 093105993

(51) Int. Cl. G01R 31/02

(52) U.S. Cl. 324/756

(57) ABSTRACT

A testing apparatus tests whether an electronic device connects correctly with a circuit board. The testing apparatus includes a transferring board, at least one connecting line and at least one circuit testing board. In this case, the transferring board has at least one transferring component, which is electrically connected with the electronic device. A first end of the connecting line is electrically connected with the transferring board. The circuit testing board is electrically connected with a second end of the connecting line. The circuit testing board further has at least one testing point, which is electrically connected with the transferring component. Furthermore, a testing method for testing whether an electronic device connects correctly with a circuit board is also disclosed.

### CROSS REFERENCE TO RELATED APPLICATIONS

This Non-provisional application claims priority under 35 U.S.C. §119(a) on Patent Application No. 093105993 filed in Taiwan, Republic of China on Mar. 5, 2004, the entire contents of which are hereby incorporated by reference.

### BACKGROUND OF THE INVENTION

1. Field of Invention

The invention relates to a testing apparatus and a testing method, and more particularly to a testing apparatus having a circuit testing board and capable of transferring a testing point of an electronic device to a circuit testing board for test so as to identify whether the electronic device correctly and electrically connects with a computer mainboard, and a testing method using the testing apparatus.

2. Related Art

During the production process of a typical computer mainboard, a series of testing procedures has to be performed in order to verify whether each function of the computer mainboard is normal.

During each testing procedure for testing a CPU socket, the prior art has to insert a CPU chip into the socket before the test starts and remove the CPU chip from the socket after the test ends. If the inserting and removing operations are not carefully performed, the pins on the CPU chip tend to be bent or broken.

Then, in order to reduce the great damage when the CPU chips are being tested, a chip transferring board is usually used to replace the CPU chip for test, wherein the transferring board has the same electrical connection points as the CPU chip. Then, the adapter pins of the chip transferring board are inserted into the CPU socket. Consequently, the transferring board rather than the CPU chip becomes the member to be repeatedly inserted into or removed from the CPU socket during the test procedure.

As shown in FIG. 1, a CPU socket 11 is bonded to a computer mainboard 12, and the CPU socket 11 has a plurality of first holes 111. In order to test whether the CPU socket 11 correctly and electrically connects with the computer mainboard 12 in the prior art, a transferring board 13 is used to assist in testing. The transferring board 13 has connection points. For example, the transferring board 13 has adapter pins 131, which correspond to the first holes 111 of the CPU socket 11, at a side, and second holes 132, which communicate with the adapter pins at the other side.

A testing unit 14 has micro-probes 141 corresponding to the second holes 132. During the test, the micro-probes 141 are inserted into the second holes 132 of the transferring board 13 in order to detect whether the associated functions of the CPU socket 11 on the computer mainboard 12 are normal and whether the connections of the CPU socket 11 are normal.

With the increase of the number of pins of the CPU chip, however, the numbers of the adapter pins 131 and the second holes 132 on the transferring board 13 also increase, and the aperture of each second hole 132 is getting smaller and smaller in a constant area on the transferring board 13, which causes too-large pressures on the micro-probes 141 inserted into the second holes 132 and the thin and long micro-probes 141 tend to be broken in the second holes 132. Thus, the testing unit 14 or even the CPU socket 11 and the transferring board 13 may be damaged, the testing procedures cannot be smoothly performed, and the lifetime of the transferring board 13 is thus shortened.

In addition, the connection points on the prior art transferring board 13 also may be formed in the form of pads. The pads at one side of the transferring board 13 are in contact with elastic members of the CPU socket 11, and the pads on the other side of the transferring board 13 serve as the connection points to be in contact with the micro-probes 141 of the testing unit 14, wherein the pads on two sides of the transferring board 13 connect with each other. However, the transferring board 13 with the pads has to contact the elastic members so that the testing procedures can be performed. So, relative large pressures have to be applied during the testing procedures such that the pads can tightly contact the elastic members. This, however, tends to cause too large forces applied to the CPU socket 11 and the transferring board 13, and thus to cause the damage.

In view of the above-mentioned problems, it is therefore an important subject of the invention to provide a testing apparatus and a testing method capable of solving the problem of difficulty in testing the CPU socket due to the increase of the number of pins of the CPU chip.

### SUMMARY OF THE INVENTION

In view of the foregoing, the invention is to provide a testing apparatus and a testing method, and particularly a testing apparatus having a circuit testing board and capable of transferring a testing point of an electronic device to the circuit testing board for test so as to identify whether the electronic device correctly and electrically connects with a computer mainboard, and a testing method using the testing apparatus.

To achieve the above, the invention provides a testing apparatus for testing whether an electronic device connects correctly with a circuit board. The testing apparatus includes a transferring board, at least one connecting line and at least one circuit testing board. In this case, the transferring board has at least one transferring component and the transferring component is electrically connected with the electronic device. A first end of the connecting line is electrically connected with the transferring board. A second end of the connecting line is electrically connected with the circuit testing board. The circuit testing board further has at least one testing point, which is electrically connected with the transferring component.

To achieve the above, the invention also provides a testing method for testing whether an electronic device connects correctly with a circuit board. The method comprises the steps of: electrically connecting a first end of a connecting line with a transferring board; electrically connecting a second end of the connecting line with a circuit testing board; electrically connecting the transferring board with the electronic device; and electrically connecting a testing unit with the circuit testing board.

As mentioned above, the testing apparatus of the invention has at least one circuit testing board and is capable of transferring the testing point, which is electrically connecting with the transferring board of the electronic device, to the circuit testing board according to the electrical connection with the connecting line so as to facilitate the testing unit to test whether the electronic device correctly and electrically connects with the computer mainboard directly on the circuit testing board. Compared to the prior art, the testing apparatus and method of the invention solve the problem of the damaged transferring board and testing unit when the conventional electronic device is being tested owing to the number of pins of the chip is increased and the pressure is too large during the testing processes of the testing unit and the transferring board. Because the testing apparatus and method of the invention transfer the testing point on the transferring board to the circuit testing board for test, it is possible to utilize the connecting line to test on more than two circuit testing boards when the number of the to-be-tested connection points of the electronic device is too great. In addition, the circuit testing board further may be disposed on a supporting frame, which crosses over the electronic device. Thus, the testing unit can directly test the circuit testing board above the original position of the electronic device without occupying the space of other electronic devices.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a testing apparatus for a conventional CPU socket;

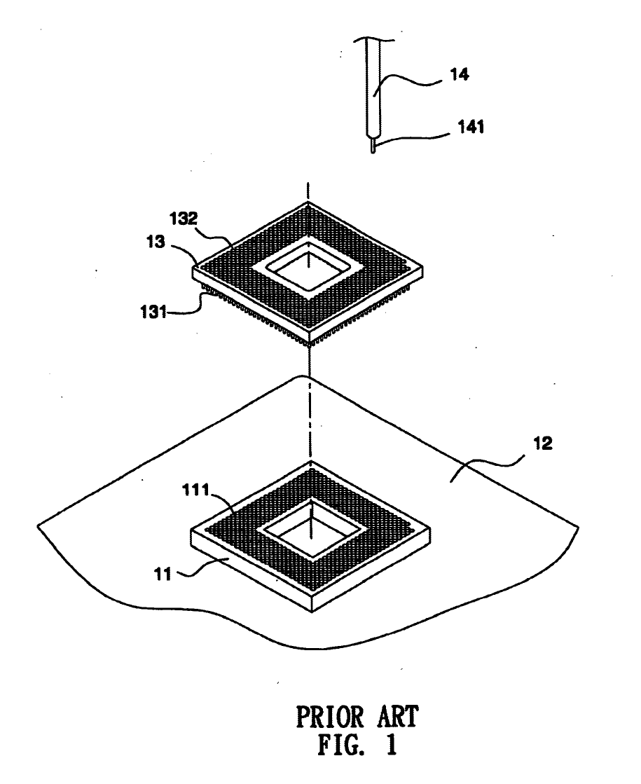

FIG. 2 is a schematic illustration showing a testing apparatus of the invention;

FIG. 3 is a schematic illustration showing a transferring board, a connecting line and a circuit testing board of the invention;

FIG. 4 is another schematic illustration showing the transferring board, the connecting line and the circuit testing board of the invention;

FIG. 5 is a schematic illustration showing the electronic device and the circuit testing board of the invention;

FIG. 6 is another schematic illustration showing the testing apparatus of the invention;

FIG. 7 is a flow chart showing a testing method of the invention; and

FIG. 8 is another flow chart showing the testing method of the invention.

### DETAILED DESCRIPTION OF THE INVENTION

The present invention will be apparent from the following detailed description, which proceeds with reference to the accompanying drawings, wherein the same references relate to the same elements.

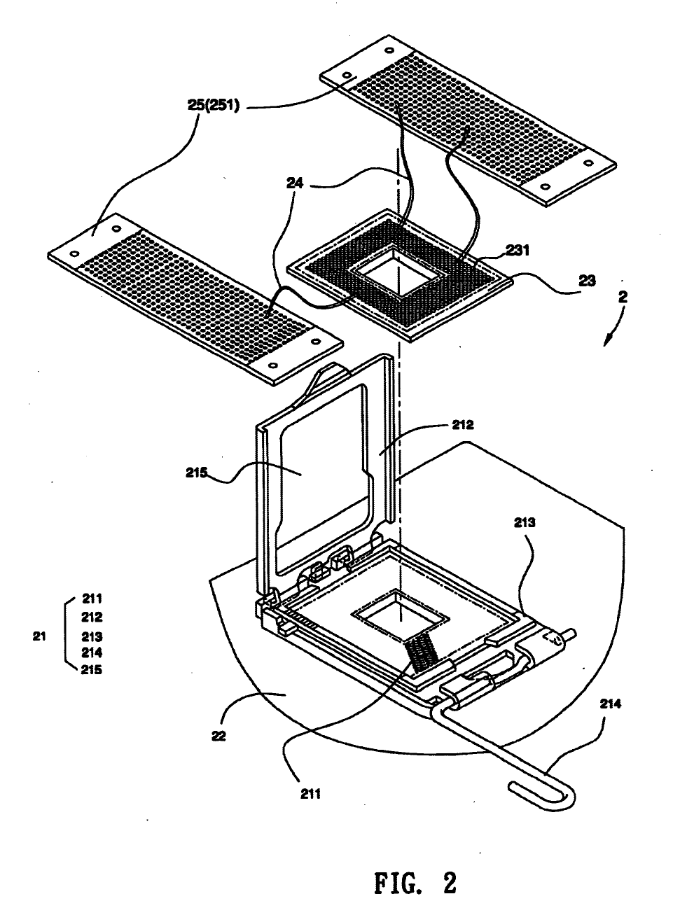

A testing apparatus 2 according to a preferred embodiment of the invention will be described with reference to FIGS. 2 to 6.

As shown in FIG. 2, the testing apparatus 2 is for testing whether an electronic device 21 connects correctly with a circuit board 22. The testing apparatus 2 includes a transferring board 23, at least one connecting line 24 and at least one circuit testing board 25.

In FIG. 2, the electronic device 21 is connected with the circuit board 22 and may be a socket. In this embodiment, for example, the electronic device 21 is a CPU socket in a notebook computer. In this embodiment, the electronic device 21 has a plurality of elastic members 211.

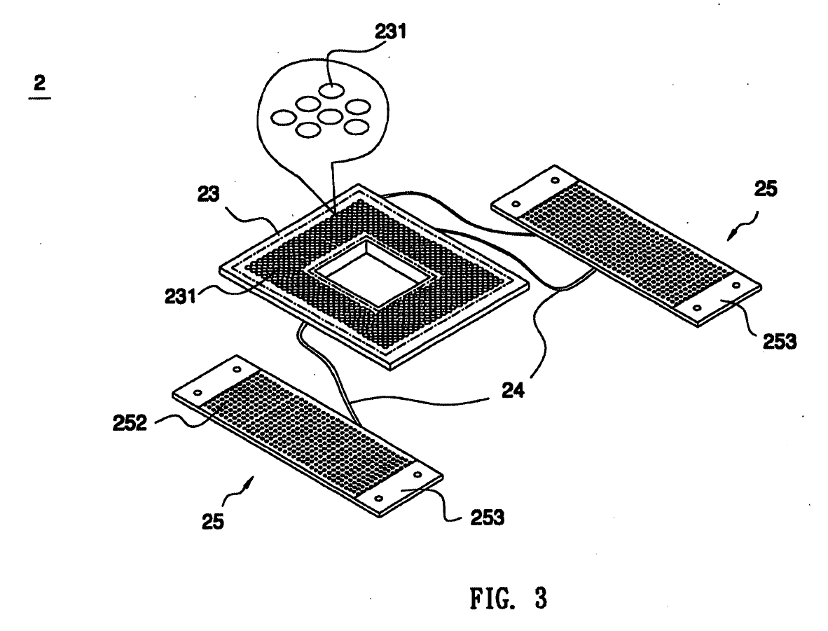

Referring to FIGS. 3 and 2, the transferring board 23 has at least one transferring component 231, which is electrically connected with the electronic device 21. In this embodiment, the transferring board 23 is used to replace the chip and to test whether the electronic device 21 connects correctly with the circuit board 22. So, the transferring board 23 and the chip have the same conductive points to be electrically connected with the electronic device 21.

In this case, at least one portion of the transferring component 231 is an exposed conductive region on the transferring board 23. In this embodiment, two ends of the transferring component 231 are pads, wherein one end contacts the elastic member 211 of the electronic device, and the other end connects with the connecting line 24. Of course, one end of the transferring component 231 may be an adapter pin or a probe projecting over the transferring board 23, and this end is inserted into the electronic device 21. In addition, one end of the transferring component 231 may be a conductive through hole to be in contact with the projecting elastic member 211 of the electronic device 21.

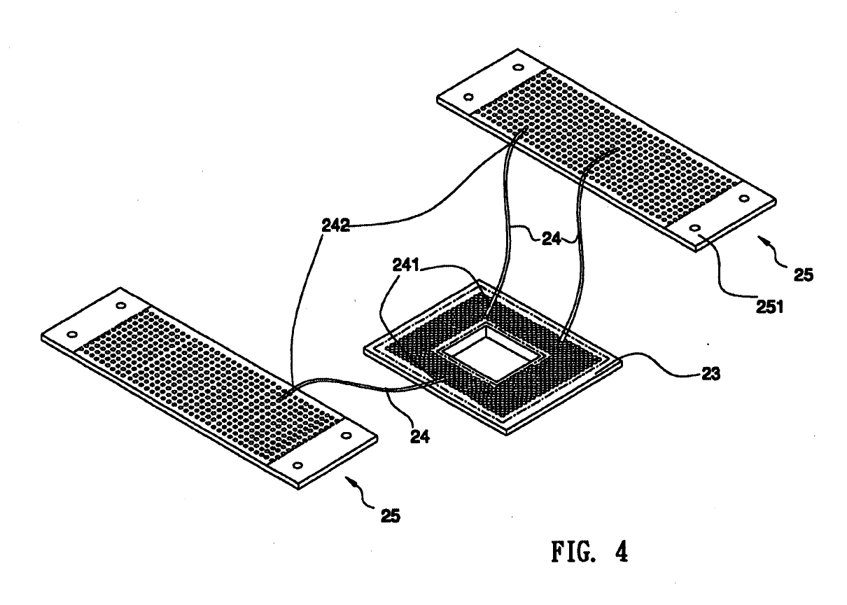

As shown in FIG. 4, a first end 241 of the connecting line 24 is electrically connected with the transferring board 23, and the connecting line 24 is a FPC (Flexible Print Circuit) or an electrical line. The FPC is a flexible printed circuit, which has a high reliability and is made of a polyester film or polyimide serving as the base material. A second end 242 of the connecting line 24 is electrically connected with a first surface 251 of the circuit testing board 25.

Referring again to FIG. 3, the circuit testing board 25 includes a testing point 252, which is an exposed conductive region on the circuit testing board 25. The testing point 252 is located on a second surface 253 of the circuit testing board 25. The first surface 251 of the circuit testing board 25 is opposite to the second surface 253, and the testing point 252 is electrically connected with the transferring component 231.

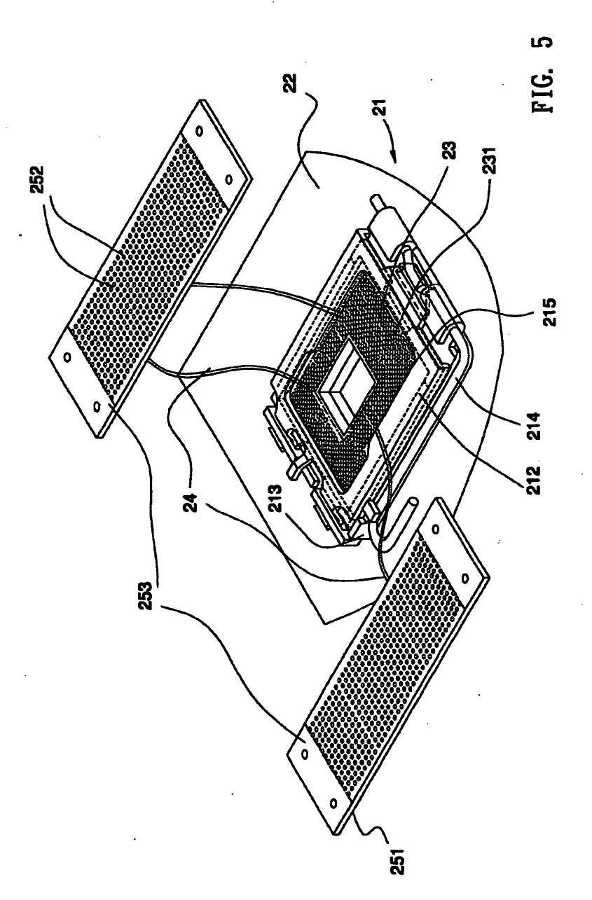

The electronic device 21 of this embodiment is fixed to the circuit board 22, as shown in FIG. 5. The electronic device 21 further has a cover 212, a base 213, a handle 214 and an upper cover opening 215.

The transferring board 23 is placed on the elastic member 211 of the electronic device 21 such that the electronic device 21 is connected with the transferring board 23. The electronic device 21 is electrically connected with the transferring component 231. After the electronic device 21 is connected with the transferring board 23, the cover 212 is closed and fastened to the base 213 using the handle 214. Thus, the transferring board 23 is fixed to the electronic device 21.

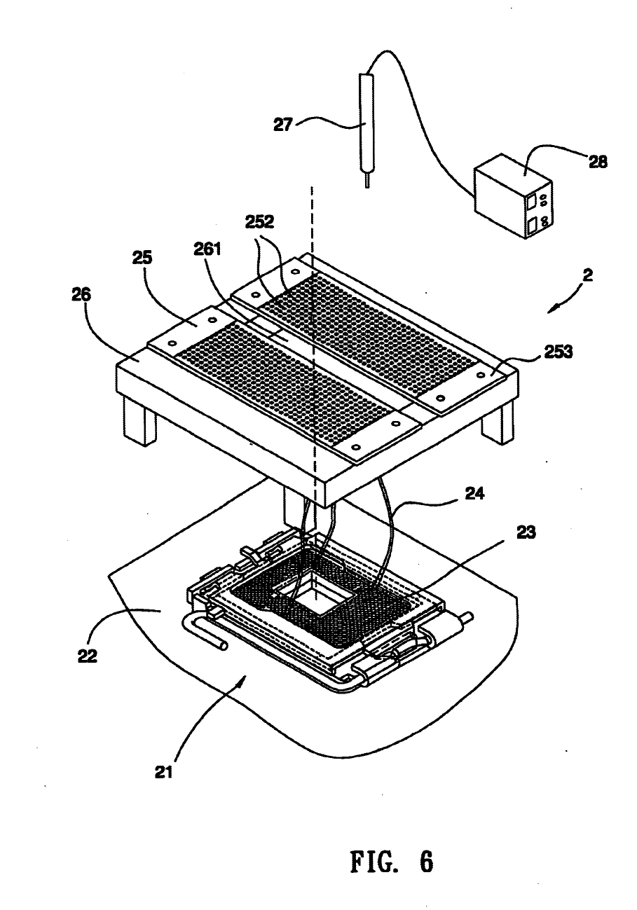

Referring to FIG. 6, the testing apparatus 2 of this embodiment further includes a supporting frame 26, which crosses over the electronic device 21 and is disposed on the circuit board 22. The supporting frame 26 has an opening 261, through which the connecting line 24 connected with the transferring board 23 is connected with the circuit testing board 25 placed on the supporting frame 26. Hence, the supporting frame 26 supports the circuit testing board 25 such that the circuit testing board 25 is located above the electronic device 21, and the testing point 252 of the circuit testing board 25 having the second surface 253 faces upwards so as to facilitate the testing step.

This embodiment further includes at least one testing unit 27 and a monitoring unit 28 electrically connected with the testing unit 27. When it is tested whether the electronic device 21 connects correctly with the circuit board 22, the testing unit 27 is electrically connected with the testing point 252, and the monitoring unit 28 electrically connected with the testing unit 27 identifies that the electronic device 21 is in an electrical connection state, and whether it is normally connected with the circuit board 22.

The testing method according to the preferred embodiment of the invention will be described with reference to FIGS. 3 to 8.

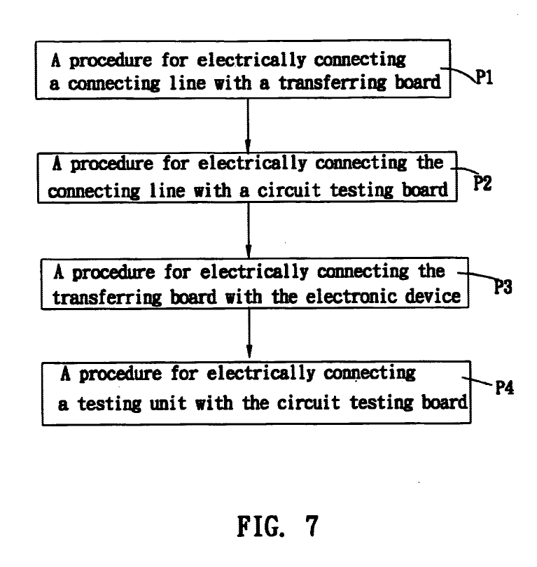

Referring to FIG. 7, the testing method according to the preferred embodiment of the invention is for testing whether an electronic device connects correctly with a circuit board. The testing method includes a procedure P1 for electrically connecting a connecting line with a transferring board, a procedure P2 for electrically connecting the connecting line with a circuit testing board, a procedure P3 for electrically connecting the transferring board with the electronic device, and a procedure P4 for electrically connecting a testing unit with the circuit testing board.

The electronic device is connected with the circuit board and may be a socket. In this embodiment, for example, the electronic device is a CPU socket of a notebook computer.

In the procedure P1 of FIG. 7 for electrically connecting the connecting line with the transferring board, a first end 241 of the connecting line 24 is electrically connected with the transferring board 23, as shown in FIG. 4. The connecting line 24 is a FPC (Flexible print circuit, FPC) or an electrical line. In this embodiment, the connecting line 24 is an electrical line for connecting the first end 241 of the connecting line 24 with the testing point on the transferring board 23 by way of bonding.

As shown in FIGS. 3 and 2, the transferring board 23 has at least one transferring component 231, which is electrically connected with the electronic device 21. In this case, the portion of the transferring component 231 is an exposed conductive region on the transferring board 23. In this embodiment, the transferring component 231 is a pad to be in contact with the elastic member 211 of the electronic device. Of course, one end of the transferring component 231 may be an adapter pin or a probe projecting over the transferring board 23, and this end is inserted into the electronic device 21. In addition, one end of the transferring component 231 may be a conductive through hole to be in contact with the elastic member 211 projecting over the electronic device 21.

In the procedure P2 of FIG. 7 for electrically connecting the connecting line with the circuit testing board, a second end 242 of the connecting line 24 is electrically connected with a circuit testing board 25. As shown in FIG. 4, a first surface 251 of the circuit testing board 25 is electrically connected with the second end 242 of the connecting line 24.

Referring again to FIG. 3, the circuit testing board 25 further includes at least one testing point 252, which is an exposed conductive region on the circuit testing board 25. The testing point 252 is located on a second surface 253 of the circuit testing board 25. The first surface 251 of the circuit testing board 25 is opposite to the second surface 253, and the testing point 252 is electrically connected with the transferring component 231.

In the procedure P3 of FIG. 7 for electrically connecting the transferring board with the electronic device, the transferring board 23 is electrically connected with the electronic device 21 by placing the transferring board 23 on the elastic member 211 of the electronic device 21, as shown in FIG. 2. Meanwhile, the transferring component 231 is also electrically connected with the electronic device 21. After the procedure P3 for electrically connecting the transferring board with the electronic device, the circuit testing board 25 is also electrically connected with the electronic device 21. Next, the procedure P4 of FIG. 7 for electrically connecting the testing unit with the circuit testing board is performed.

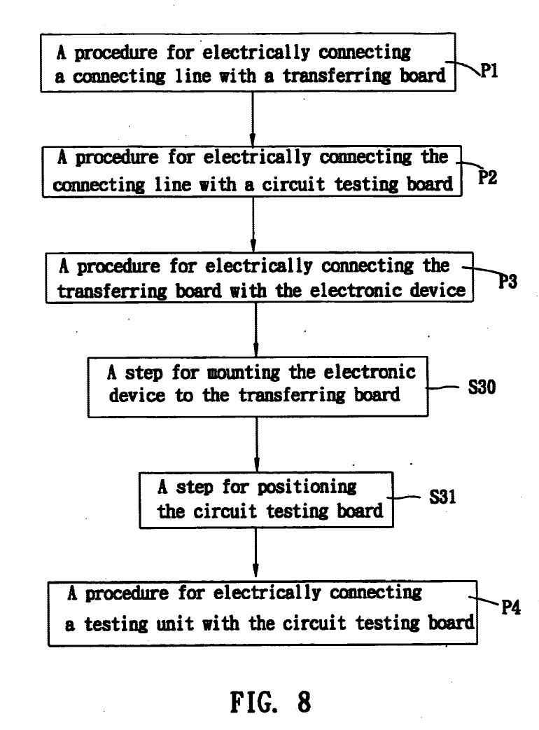

Referring to FIG. 8, the testing method of the invention may further include a step S30 for mounting the electronic device to the transferring board. As shown in FIG. 5, the electronic device 21 is mounted to the circuit board 22, and the electronic device 21 has a cover 212, a base 213, a handle 214 and an upper cover opening 215. The cover 212 is not closed until the connecting line 24 connected with the transferring board 23 passes through the upper cover opening 215 of the cover 212. Then, the base 213 is fastened using the handle 214 so as to complete the step S30 for mounting the electronic device to the transferring board.

The testing method of the invention may further include a step S31 of FIG. 8 for positioning the circuit testing board. As shown in FIG. 6, the circuit testing board 25, which has passed through the upper cover opening 215 and connects with the connecting line 24, is positioned on a supporting frame 26.

As shown in FIG. 6, the supporting frame 26 crosses over the electronic device 21 and is disposed on the circuit board 22. The supporting frame 26 has an opening 261, through which the connecting line 24 connected with the transferring board 23 is connected to the circuit testing board 25, which is positioned on the supporting frame 26. Consequently, the supporting frame 26 supports the circuit testing board 25 such that the circuit testing board 25 is located above the electronic device 21 and the second surface 253 of the circuit testing board 25 having the testing point 252 faces upwards to facilitate the testing procedures.

In the procedure P4 for electrically connecting the testing unit with the circuit testing board, the testing unit 27 is electrically connected with a monitoring unit 28. When it is to be identified whether the electronic device 21 connects correctly with the circuit board 22, the testing unit 27 is electrically connected with the testing point 252, and the monitoring unit 28 that is electrically connected with the testing unit 27 identifies whether the electronic device 21 is in an electrical connection state and whether the circuit board 22 is in a normal conductive state.

In summary, the testing apparatus of the invention has at least one circuit testing board and is capable of transferring electronic signals to the circuit testing board through the testing point, which is electrically connected with the electronic device and the transferring board, according to the electrical connection with the connecting line so as to facilitate the testing unit to test whether the electronic device correctly and electrically connects with the computer mainboard directly on the circuit testing board. Compared to the prior art, the testing apparatus and method of the invention solve the problem of the damaged testing unit or electronic device when the conventional electronic device is being tested owing to the number of pins of the electronic device (e.g., a chip with a great number of high density pins) is increased and the pressure applied to the probe is too large during the testing processes of the testing unit. The testing apparatus and method of the invention transfer the testing point to at least one circuit testing board, and the testing unit tests the electronic device on the circuit testing board. That is, it is possible to utilize the connecting line to lead the testing points out and to increase the number of circuit testing boards such that the pressure applied to the testing probe is reduce when the number of the to-be-test connection points of the electronic device is too great. Consequently, the testing unit or electronic device is free from being damaged, and the material cost of the testing unit may be reduced. In addition, the circuit testing board further may be disposed on a supporting frame, which crosses over the electronic device. Thus, the testing unit can directly test the circuit testing board above the original position of the electronic device without occupying the space of other electronic devices.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

1. A testing apparatus for testing whether an electronic device connects correctly with a circuit board, the testing apparatus comprising:
a transferring board having at least one transferring component, which is electrically connected with the electronic device;
at least one connecting line having a first end electrically connected with the transferring board; and
at least one circuit testing board electrically connected with a second end of the connecting line, wherein the circuit testing board has at least one testing point, which is electrically connected with the transferring component.

2. The testing apparatus according to claim 1, wherein at least one portion of the transferring component is an exposed conductive region on the transferring board.

3. The testing apparatus according to claim 1, wherein at least one portion of the transferring component projects over the transferring board, and at least one portion of the transferring component is inserted into the electronic device.

4. The testing apparatus according to claim 1, wherein the testing point is at least one exposed conductive region on the circuit testing board.

5. The testing apparatus according to claim 4, further comprising at least one testing unit and a monitoring unit electrically connected with the testing unit, wherein when the testing unit is electrically connected with the testing point, the monitoring unit identifies that the electronic device is in an electrical connection state.

6. The testing apparatus according to claim 1, wherein the connecting line is a FPC (Flexible Print Circuit) or an electrical line.

7. The testing apparatus according to claim 1, further comprising a supporting frame, on which the circuit testing board is disposed.

8. The testing apparatus according to claim 7, wherein the supporting frame crosses over the electronic device.

9. The testing apparatus according to claim 1, wherein the electronic device is a socket.

10. A testing method for testing whether an electronic device connects correctly with a circuit board, the method comprising the steps of:
electrically connecting a first end of a connecting line with a transferring board;
electrically connecting a second end of the connecting line with a circuit testing board;
electrically connecting the transferring board with the electronic device; and
electrically connecting a testing unit with the circuit testing board.

11. The method according to claim 10, further comprising the step of:
electrically connecting the testing unit with a monitoring unit, wherein when the testing unit is electrically connected with the circuit testing board, the monitoring unit identifies that the electronic device is in an electrical connection state.

12. The method according to claim 10, further comprising the step of:
disposing the circuit testing board on a supporting frame.

13. The method according to claim 10, wherein the supporting frame crosses over the electronic device.

14. The method according to claim 10, wherein the transferring board has at least one transferring component, and the transferring component is electrically connected with the electronic device.

15. The method according to claim 10, wherein at least one portion of the transferring component is an exposed conductive region on the transferring board.

16. The method according to claim 10, wherein at least one portion of the transferring component projects over the transferring board, and at least one portion of the transferring component is inserted into the electronic device.

17. The method according to claim 10, wherein the circuit testing board has at least one testing point, which is electrically connected with the transferring component.

18. The method according to claim 17, wherein the testing point is at least one exposed conductive region on the circuit testing board.

19. The method according to claim 10, wherein the connecting line is a FPC (Flexible Print Circuit) or an electrical line.

20. The method according to claim 10, wherein the electronic device is a socket.
